(19) United States
(12) Patent Application Publication
(10) Pub. No.: US 2020/0184124 A1
(43) Pub. Date: Jun. 11, 2020

(54) SYSTEMS AND METHODS FOR THROAT INSPECTION

(71) Applicant: General Electric Company, Schenectady, NY (US)

(72) Inventors: Dawid Tadeusz MACHALICA, Warszawa (PL); Bryan David LEWIS, Greenville, SC (US)

(21) Appl. No.: 16/701,356

(22) Filed: Dec. 3, 2019

(30) Foreign Application Priority Data
Dec. 6, 2018 (PL) P.428066

(51) Int. Cl. G06F 30/17; G06F 30/15; G06F 30/20; G01M 15/14

(52) U.S. Cl. CPC G06F 30/17; G01M 15/14; G06F 30/20; G06F 30/15

(57) ABSTRACT

A method includes generating inspection requirements for a radial section of a turbine nozzle by generating a resultant curve along the radial section and along a vane of the turbine nozzle, generating a middle inspection point along the resultant curve at a nominal throat location, generating first and second arrays of inspection points on sides of the middle inspection point along the resultant curve, generating a middle inspection vector normal to the middle inspection point, and generating first and second arrays of inspection vectors parallel to the middle inspection vector that intersect the resultant curve at the first and second arrays of inspection points, respectively. The inspection requirements include the middle inspection point, the middle inspection vector, the first and second arrays of inspection points, and the first and second arrays of inspection vectors. The method also includes generating a coordinate measuring machine (CMM) output file including the inspection requirements.

### BACKGROUND OF THE INVENTION

The subject matter disclosed herein relates to systems and methods for generating machine-interpretable inspection requirements for a throat, such as a throat of a nozzle.

Industrial machines, such as gas turbine systems, may provide for the generation of power. For example, the gas turbine systems typically include a compressor for compressing a working fluid, such as air, a combustor for combusting the compressed working fluid with fuel, and a turbine section for turning the combusted fluid into a rotative power. For example, the compressed air is injected into a combustor, which heats the fluid, increasing the amount of energy provided by the fluid. The heated fluid is forced through the turbine section of the gas turbine. The gas turbine may then convert the heated fluid into rotative power, for example, by a series of blade stages. The rotative power may then be used to drive a load, which may include an electrical generator producing electrical power and electrically coupled to a power distribution grid. The gas turbine may include nozzles that direct fluid flow. For example, the nozzles may include vanes that direct air through the turbine. The nozzles may be inspected for fulfillment of design requirements and to ensure efficient operation of the gas turbine.

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In a first embodiment, a method includes generating, via a processor, a first set of inspection requirements for a first radial section between a first vane and a second vane of a turbine nozzle using an inspection requirement generation process. The inspection requirement generation process includes generating a first resultant curve along the first radial section of the turbine nozzle in a three-dimensional (3D) computer-aided design (CAD) model, where the first resultant curve is disposed along the first vane, generating a middle inspection point along the first resultant curve at a nominal throat location between the first vane and the second vane, generating a first array of inspection points at intersection locations of a first array of planes and the first resultant curve on a first side of the middle inspection point along the first resultant curve, where the first array of planes are generally parallel to the nominal throat location, and generating a second array of inspection points at intersection locations of a second array of planes and the first resultant curve on a second side of the middle inspection point along the first resultant curve, where the second array of planes are generally parallel to the nominal throat location. The inspection requirement generation process also includes generating a middle inspection vector, where the middle inspection vector is normal to the first vane at the middle inspection point, generating a first array of inspection vectors on a first side of the middle inspection vector, where each inspection vector of the first array of inspection vectors is parallel to the middle inspection vector and intersects the first resultant curve at a respective inspection point of the first array of inspection points, and generating a second array of inspection vectors on a second side of the middle inspection vector, where each inspection vector of the second array of inspection vectors is parallel to the middle inspection vector and intersects the first resultant curve at a respective inspection point of the second array of inspection points. The first set of inspection requirements includes the middle inspection point measured from the middle inspection vector, the first array of inspection points measured from respective inspection vectors of the first array of inspection vectors, and the second array of inspection points measured from respective inspection vectors of the second array of inspection vectors. The method also includes generating a coordinate measuring machine (CMM) output file including the first set of inspection requirements.

In another embodiment, a computer aided technologies (CAx) system includes a processor configured to generate a first set of inspection requirements for a first radial section between a first vane and a second vane of a turbine nozzle using an inspection requirement generation process. The inspection requirement generation process includes generating a first resultant curve along the first radial section of the turbine nozzle in a three-dimensional (3D) computer-aided design (CAD) model, where the first resultant curve is disposed along the first vane, generating a middle inspection point along the first resultant curve at a nominal throat location between the first vane and the second vane, generating a first array of inspection points at intersection locations of a first array of planes and the first resultant curve on a first side of the middle inspection point along the first resultant curve, where the first array of planes are generally parallel to the nominal throat location, and generating a second array of inspection points at intersection locations of a second array of planes and the first resultant curve on a second side of the middle inspection point along the first resultant curve, where the second array of planes are generally parallel to the nominal throat location. The inspection requirement generation process also includes generating a middle inspection vector, where the middle inspection vector is normal to the first vane at the middle inspection point, generating a first array of inspection vectors on a first side of the middle inspection vector, where each inspection vector of the first array of inspection vectors is parallel to the middle inspection vector and intersects the first resultant curve at a respective inspection point of the first array of inspection points, and generating a second array of inspection vectors on a second side of the middle inspection vector, where each inspection vector of the second array of inspection vectors is parallel to the middle inspection vector and intersects the first resultant curve at a respective inspection point of the second array of inspection points. The first set of inspection requirements includes the middle inspection point measured from the middle inspection vector, the first array of inspection points measured from respective inspection vectors of the first array of inspection vectors, and the second array of inspection points measured from respective inspection vectors of the second array of inspection vectors. The processor is also configured to generate a coordinate measuring machine (CMM) output file including the first set of inspection requirements.

In yet another embodiment, a tangible, non-transitory, computer-readable medium comprising instructions that, when executed, are configured to cause a processor to generate a first set of inspection requirements for a first radial section between a first vane and a second vane of a turbine nozzle using an inspection requirement generation process. The inspection requirement generation process includes generating a first resultant curve along the first radial section of the turbine nozzle in a three-dimensional (3D) computer-aided design (CAD) model, where the first resultant curve is disposed along the first vane, generating a middle inspection point along the first resultant curve at a nominal throat location between the first vane and the second vane, generating a first array of inspection points at intersection locations of a first array of planes and the first resultant curve on a first side of the middle inspection point along the first resultant curve, where the first array of planes are generally parallel to the nominal throat location, and generating a second array of inspection points at intersection locations of a second array of planes and the first resultant curve on a second side of the middle inspection point along the first resultant curve, where the second array of planes are generally parallel to the nominal throat location. The inspection requirement generation process also includes generating a middle inspection vector, where the middle inspection vector is normal to the first vane at the middle inspection point, generating a first array of inspection vectors on a first side of the middle inspection vector, where each inspection vector of the first array of inspection vectors is parallel to the middle inspection vector and intersects the first resultant curve at a respective inspection point of the first array of inspection points, and generating a second array of inspection vectors on a second side of the middle inspection vector, where each inspection vector of the second array of inspection vectors is parallel to the middle inspection vector and intersects the first resultant curve at a respective inspection point of the second array of inspection points. The first set of inspection requirements includes the middle inspection point measured from the middle inspection vector, the first array of inspection points measured from respective inspection vectors of the first array of inspection vectors, and the second array of inspection points measured from respective inspection vectors of the second array of inspection vectors. The instructions are also configured to cause the processor to generate a coordinate measuring machine (CMM) output file including the first set of inspection requirements.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a block diagram of an embodiment of a computer-aided technology (CAx) system, in accordance with one or more embodiments of the current disclosure;

FIG. 2 is a block diagram of embodiments certain components of the CAx system of FIG. 1, in accordance with one or more embodiments of the current disclosure;

FIG. 3 is a block diagram of an embodiment of an industrial system that may be conceived, designed, engineered, manufactured, and/or service and tracked by the CAx system of FIG. 1, in accordance with one or more embodiments of the current disclosure;

FIG. 4 is flow chart of an embodiment of a process suitable for generating a set of inspection requirements for a turbine nozzle using the CAx system of FIG. 1, in accordance with one or more embodiments of the current disclosure;

FIG. 5 is a perspective view of an embodiment of a turbine nozzle having radial sections, in accordance with one or more embodiments of the current disclosure;

FIG. 6 is a cross-sectional view of an embodiment of the turbine nozzle of FIG. 5 having a nominal throat area between a first vane and a second vane, in accordance with one or more embodiments of the current disclosure;

FIG. 7 is a perspective cross-sectional view of an embodiment of a first vane of the turbine nozzle of FIG. 5 along a first radial section and inspection points of a first set of inspection requirements that may be generated by the CAx system of FIG. 1, in accordance with one or more embodiments of the current disclosure;

FIG. 8 is a perspective cross-sectional view of an embodiment of a first vane of the turbine nozzle of FIG. 5 along a first radial section and inspection points and inspection vectors of the first set of inspection requirements that may be generated by the CAx system of FIG. 1, in accordance with one or more embodiments of the current disclosure;

FIG. 9 is a perspective cross-sectional view of an embodiment of a second vane of the turbine nozzle of FIG. 5 along the first radial section and inspection points of a second set of inspection requirements that may be generated by the CAx system of FIG. 1, in accordance with one or more embodiments of the current disclosure;

FIG. 10 is a perspective cross-sectional view of an embodiment of a second vane of the turbine nozzle of FIG. 5 along the first radial section and inspection points and inspection vectors of the second set of inspection requirements that may be generated by the CAx system of FIG. 1, in accordance with one or more embodiments of the current disclosure;

FIG. 11 is flow chart of an embodiment of a process suitable for measuring and determining a throat location of the turbine nozzle of FIG. 5, using the first set of inspection requirements and the second set of inspection requirements, in accordance with one or more embodiments of the current disclosure; and

FIG. 12 is a cross-sectional view of an embodiment of the first vane and the second vane of FIG. 6 with measured points along the first vane and the second vane, in accordance with one or more embodiments of the current disclosure.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

Designing a machine or part may include certain systems and methods described in more detail below that produce a design for a part or product. For example, the design may be created as a model-based definition included in a 3-dimensional (3D) computer aided design (CAD) model and associated product and manufacturing information (PMI). The part or product may be manufactured based on the design. Before inspection of the resulting part or product, the techniques described herein may enable a user to automatically generate inspection requirements (e.g., sets of machine-interpretable inspection instructions) for the 3D CAD model.

In certain embodiments, the machine or part may be a power generation system. For example, the 3D model may include a power generation system having throats along certain portions of the power generation system. As described herein, a turbine nozzle of the power generation system may include a throat between two vanes. However, the present disclosure is not intended to be limited to a turbine nozzle. For example, other portions of the power generation system (e.g., a compressor, a turbine, a combustion chamber, etc.) may include a throat. The vanes of the turbine nozzle may guide a fluid flow through the power generation system, and the throat of the turbine nozzle may be an area at which the fluid flow is most restricted between the two vanes. The size and location of the throat may be used to determine certain operating parameters of the power generation system (e.g., efficiency, generated power, fuel consumption).

Further, the nozzle may be inspected to determine a location and size of the throat along the nozzle. For example, the inspection requirements described herein may be generated using the 3D CAD model to enable inspection of the nozzle and to determine the size and the location of the throat. The inspection requirements may include inspection points and corresponding inspection vectors for measuring the inspection points. The inspection points and inspection vectors allow for greater consistency and easier comparison among inspection reports, as well as greater consistency in comparing throat locations and throat sizes among different nozzles.

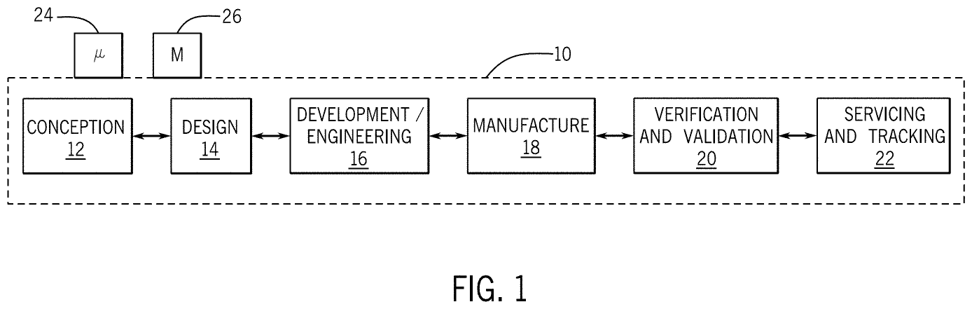

With the foregoing in mind, it may be useful to describe a computer-aided technologies (CAx) system that may incorporate the techniques described herein, for example to improve product lifecycle management (PLM) processes. Accordingly, FIG. 1 illustrates an embodiment of a CAx system 10 suitable for providing for a variety of processes, including PLM processes 12, 14, 16, 18, 20, 22. In the depicted embodiment, the CAx system 10 may include support for execution of conception processes 12. For example, the conception processes 12 may produce a set of specifications such as requirements specifications documenting a set of requirements to be satisfied by a design, a part, a product, or a combination thereof. The conception processes 12 may also produce a concept or prototype for the part or product (e.g., machinery, electronics, structures, or a combination thereof). A series of design processes 14 may then use the specifications and/or prototype to produce, for example, one or more 3D design models of the part or product. The 3D design models may include solid/surface modeling, parametric models, wireframe models, vector models, non-uniform rational basis spline (NURBS) models, geometric models, and the like, describing part geometries and structures. Additionally, as described in detail below, the 3D design models may be used to generate inspection requirements.

Design models may then be further refined and added to via the execution of development/engineering processes 16. The development/engineering processes may, for example, create and apply models such as thermodynamic models, low cycle fatigue (LCF) life prediction models, multibody dynamics (MBD) and kinematics models, computational fluid dynamics (CFD) models, finite element analysis (FEA) models, and/or 3-dimension to 2-dimension FEA mapping models that may be used to predict the behavior of the part or product during its operation. For example, turbine blades may be modeled to predict fluid flows, pressures, clearances, and the like, during operations of a gas turbine engine. Further, certain models may include nominal throats that may affect such fluid flows, pressures, and the like. The development/engineering processes 16 may additionally result in the tolerances, materials specifications (e.g., material type, material hardness), clearance specifications, and the like.

Further, the design models may be used to generate the inspection requirements described herein. During the development/engineering processes 16, the inspection requirement generation system may iterate through a design model that includes a throat to generate inspection requirements along the throat. The inspection requirement generation system may determine a nominal throat location within the design model and may use the nominal throat location to generate the inspection requirements. For example, the design model may include a turbine nozzle having a throat. The inspection requirement generation system may determine the nominal throat location for the turbine nozzle and may generate the inspection requirements for the turbine nozzle based on the nominal throat location.

The CAx system 10 may additionally provide for manufacturing processes 18 that may include manufacturing automation support. For example, additive manufacturing models may be derived, such as 3D printing models for material jetting, binder jetting, vat photopolymerization, powder bed fusion, sheet lamination, directed energy deposition, material extrusion, and the like, to create the part or product. Other manufacturing models may be derived, such as computer numeric control (CNC) models with G-code to machine or otherwise remove material to produce the part or product (e.g., via milling, lathing, plasma cutting, wire cutting, and so on). Bill of materials (BOM) creation, requisition orders, purchasing orders, and the like, may also be provided as part of the manufacture processes 18 (or other PLM processes).

The CAx system 10 may additionally provide for verification and/or validation processes 20 that may include automated inspection of the part or product as well as automated comparison of specifications, requirements, and the like. In one example, a coordinate-measuring machine (CMM) process may be used to automate inspection of the part or product. The CMM process may be aided by the use of the inspection requirement generation system. As described above, the inspection requirement generation system may enable the user to iterate through a model (e.g., 3D model, 2D model) and select portions of the model for generation of the inspection requirements. The inspection requirements may be automatically generated, and such inspection requirements may be suitable for directing an inspection via the CMM process. For example, the generated inspection requirements may be used to inspect a manufactured turbine nozzle for determination of an actual throat of the turbine nozzle.

A servicing and tracking set of processes 22 may also be provided via the CAx system 10. The servicing and tracking processes 22 may log maintenance activities for the part, part replacements, part life (e.g., in fired hours), and so on. As illustrated, the CAx system 10 may include feedback between the processes 12, 14, 16, 18, 20, and 22. For example, data from services and tracking processes 22, for example, may be used to redesign the part or product via the design processes 14. Indeed, data from any one of the processes 12, 14, 16, 18, 20, and 22 may be automatically provided and used by any other of the processes 12, 14, 16, 18, 20, and 22 to improve the part or product or to create a new part or a new product. In this manner, the CAx system 10 may incorporate data from downstream (or upstream) processes and use the data to improve the part or to create a new part.

The CAx system 10 may additionally include one or more processors 24 and a memory system 26 that may execute software programs to perform the disclosed techniques. Moreover, the processors 24 may include multiple microprocessors, one or more “general-purpose” microprocessors, one or more special-purpose microprocessors, and/or one or more application specific integrated circuits (ASICS), or some combination thereof. For example, the processors 24 may include one or more reduced instruction set (RISC) processors. The processors may additionally be included in a cloud-based system that provides for the processes 12, 14, 16, 18, 20, and 22 as cloud-based services. The memory system 26 may store information such as control software, look up tables, configuration data, etc. The memory system 26 may include a tangible, non-transitory, machine-readable medium, such as a volatile memory (e.g., a random access memory (RAM)) and/or a nonvolatile memory (e.g., a read-only memory (ROM), flash memory, a hard drive, or any other suitable optical, magnetic, or solid-state storage medium, or a combination thereof).

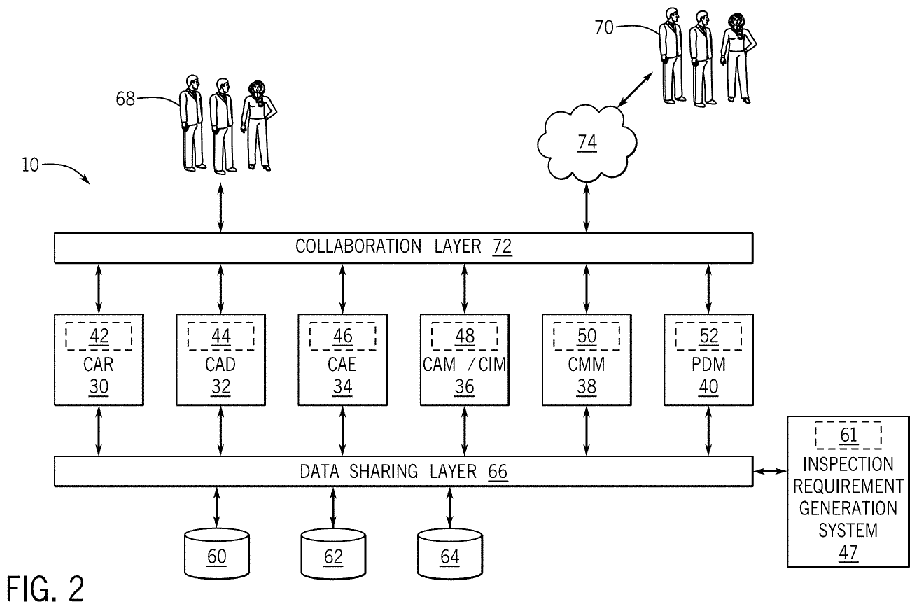

The memory system 26 may store a variety of information, which may be suitable for various purposes. For example, the memory system 26 may store machine-readable and/or processor-executable instructions (e.g., firmware or software) for the processors' 24 execution. In one embodiment, the executable instructions include instructions for a number of PLM systems, for example software systems, as shown in the embodiment of FIG. 2. More specifically, the CAx system 10 embodiment illustrates a computer-aided requirements capture (CAR) system 30, a computer-aided design (CAD) system 32, a computer-aided engineering (CAE) system 34, computer-aided manufacturing/computer-integrated manufacturing (CAM/CIM) system 36, a coordinate-measuring machine (CMM) system 38, a product data management (PDM) system 40, and an inspection requirement generation system 47. Each of the systems 30, 32, 34, 36, 38, 40, and 47 may be extensible and/or customizable; accordingly, each system 30 may include an extensibility and customization system 42, 44, 46, 48, 50, and 52, respectively. Additionally, each of the systems 30, 32, 34, 36, 38, 40, and 47 may be stored in a memory system, such as memory system 26, and may be executable via a processor, such as via processors 24.

In the depicted embodiment, the CAR system 30 may provide for entry of requirements and/or specifications, such as dimensions for the part or product, operational conditions that the part or product is expected to encounter (e.g., temperatures, pressures), certifications to be adhered to, quality control requirements, performance requirements, and so on. The CAD system 32 may provide for a graphical user interface suitable to create and manipulate graphical representations of 2D and/or 3D models as described above with respect to the design processes 14. For example, the 3D design models may include solid/surface modeling, parametric models, wireframe models, vector models, non-uniform rational basis spline (NURBS) models, geometric models, and the like. The CAD system 32 may provide for the creation and update of the 2D and/or 3D models and related information (e.g., views, drawings, annotations, notes, and so on). Indeed, the CAD system 32 may combine a graphical representation of the part or product with other, related information.

The CAE system 34 may enable creation of various engineering models, such as the models described above with respect to the development/engineering processes 16. For example, the CAE system 34 may apply engineering principles to create models such as thermodynamic models, low cycle fatigue (LCF) life prediction models, multibody dynamics (MBD) and kinematics models, computational fluid dynamics (CFD) models, finite element analysis (FEA) models, and/or 3-dimension to 2-dimension FEA mapping models. The CAE system 34 may then apply the aforementioned models to analyze certain part or product properties (e.g., physical properties, thermodynamic properties, fluid flow properties, and so on), for example, to better match the requirements and specifications for the part or product.

In certain embodiments, the inspection requirement generation system 47 may interface with the CAD system 32 and/or the CAE system 34 to generate the inspection requirements. For example, the inspection requirement generation system 47 may iterate through a model, such as a model produced via the CAD system 32, and may generate inspection requirements for subsequent inspection. The inspection requirements may be automatically generated by the inspection requirement generation system 47 and/or may be partially generated based on user input. A CMM input file including the inspection requirements may then be automatically generated and output by the inspection requirement generation system 47. The CMM input file may be suitable for directing an inspection via the CMM system 38.

For example, the inspection requirements generated by the inspection requirement generation system 47 may include inspection points and corresponding inspection vectors along certain portions of the model. In certain embodiments, the model may include a nozzle having a throat formed between two vanes. The inspection requirement generation system 47 may generate the inspection requirements along each of the two vanes. The inspection requirements may be included in the CMM input file for subsequent inspection by the CMM system 38.

The CAM/CIM system 36 may provide for certain automation and manufacturing efficiencies, for example, by deriving certain programs or code (e.g., G-code) and then executing the programs or code to manufacture the part or product. The CAM/CIM system 36 may support certain automated manufacturing techniques, such as additive (or subtractive) manufacturing techniques, including material jetting, binder jetting, vat photopolymerization, powder bed fusion, sheet lamination, directed energy deposition, material extrusion, milling, lathing, plasma cutting, wire cutting, or a combination thereof. The CMM system 38 may include machinery to automate inspections. For example, probe-based, camera-based, and/or sensor-based machinery may automatically inspect the part or product to ensure compliance with certain design geometries, tolerances, shapes, and so on.

As described above, the inspection requirement generation system 47 may generate and output a CMM input file to direct inspection via the CMM system 38. In this manner, the inspection requirement generation system 47 may enable the CMM system 38 to inspect a throat area (e.g., an area between two vanes of a turbine nozzle). The CMM system 38 may perform an inspection of the throat area and provide precise measurements in accordance with the inspection requirements of the CMM input file.

The measurements obtained via the CMM system 38 may be used to determine an actual throat location and size. Knowledge of the throat location and size may enable the user to determine various technical characteristics (e.g., flow rate, efficiency, generated power, fuel consumption) of the turbine. Additionally, results from the inspection may be used as inputs to supply chain systems to provide for certain material, parts, and so on, used in manufacturing the inspected part. The results from the inspection may be further used to provide feedback to other processes, such as processes 12, 14, 16, 18, 20, 22.

The PDM system 40 may be responsible for the management and publication of data from the systems 30, 32, 34, 36, 38, 40, and/or 47. For example, the systems 30, 32, 34, 36, 38, 40, and 47 may communicate with data repositories 60, 62, 64 via a data sharing layer 66. The PDM system 40 may then manage collaboration between the systems 30, 32, 34, 36, 38, 40, and 47 by providing for data translation services, versioning support, archive management, notices of updates, and so on. The PDM system 40 may additionally provide for business support such as interfacing with supplier/vendor systems and/or logistics systems for purchasing, invoicing, order tracking, and so on. The PDM system 40 may also interface with service/logging systems (e.g., service center data management systems) to aid in tracking the maintenance and life cycle of the part or product as it undergoes operations. Teams 68 and 70 may collaborate with team members via a collaboration layer 72. The collaboration layer 72 may include web interfaces, messaging systems, file drop/pickup systems, and the like, suitable for sharing information and a variety of data. The collaboration layer 72 may also include cloud-based systems 74 or communicate with the cloud-based systems 74 that may provide for decentralized computing services and file storage. For example, portions (or all) of the systems 30, 32, 34, 36, 38, 40, and 47 may be stored in the cloud 74 and/or accessible via the cloud 74.

The extensibility and customization systems 42, 44, 46, 48, 50, 52, and 61 may provide for functionality not found natively in the CAR system 30, the CAD system 32, the CAM/CIM system 36, the CMM system 38, the PDM system 40, and/or the inspection requirement generation system 47. For example, computer code or instructions may be added to the systems 30, 32, 34, 36, 38, 40, and 47 via shared libraries, modules, software subsystems and the like, included in the extensibility and customization systems 42, 44, 46, 48, 50, 52, and/or 61. The extensibility and customization systems 42, 44, 46, 48, 50, 52, and 61 may also use application programming interfaces (APIs) included in their respective systems 30, 32, 34, 36, 38, 40, and 47 to execute certain functions, objects, shared data, software systems, and so on, useful in extending the capabilities of the CAR system 30, the CAD system 32, the CAM/CIM system 36, the CMM system 38, the PDM system 40, and/or the inspection requirement generation system 47. By enabling the processes 12, 14, 16, 18, 20, and 22, for example, via the systems 30, 32, 34, 36, 38, 40, and 47 and their respective extensibility and customization systems 42, 44, 46, 48, 50, 52, and 61, the techniques described herein may provide for a more efficient “cradle-to-grave” product lifecycle management.

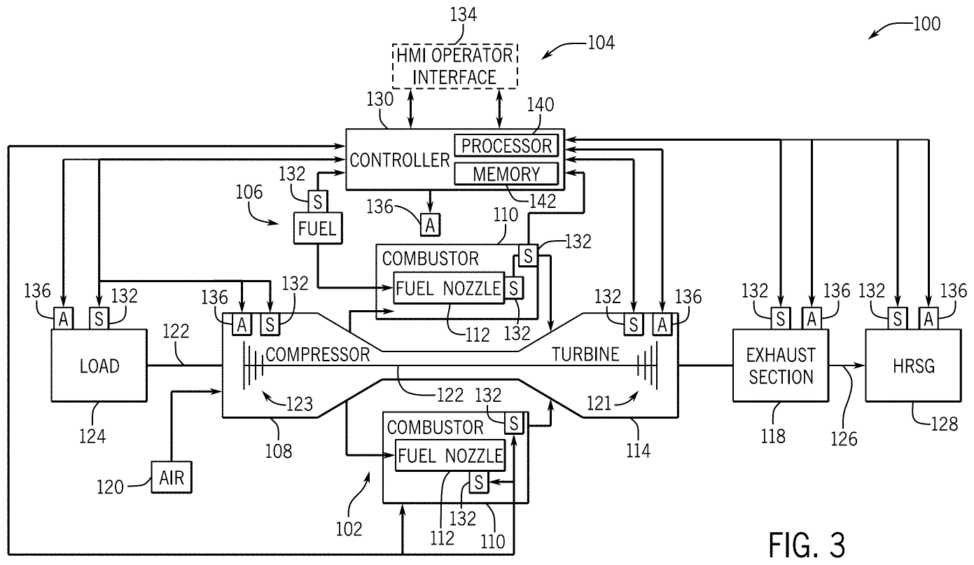

It may be beneficial to describe a machine that would incorporate one or more parts manufactured and tracked by the processes 12, 14, 16, 18, 20, and 22, for example, via the CAx system 10. Accordingly, FIG. 3 illustrates an example of a power production system 100 that may be entirely (or partially) conceived, designed, engineered, manufactured, serviced, and tracked by the CAx system 10. As illustrated in FIG. 3, the power production system 100 includes a gas turbine system 102, a monitoring and control system 104, and a fuel supply system 106. The gas turbine system 102 may include a compressor 108, combustion systems 110, fuel nozzles 112, a gas turbine 114, and an exhaust section 118.

In certain embodiments, portion(s) of the power production system 100 (e.g., the compressor 108, the combustion systems 110, the fuel nozzles 112, the gas turbine 114, and the exhaust section 118) may include throat(s). Certain fluids (e.g., air, fuel, etc.) may flow through the throat(s) during operation of the power production system 100. To determine flow rates, efficiencies, fuel usage, and other operating parameters of the power production system 100, knowledge of the location and the size of an actual throat may be beneficial. For example, the location and the size of an actual throat may be used to adjust an amount of fuel provided to the power production system 100. As such, the inspection requirement generation system 47 may generate the inspection requirements to enable determination of the location and the size of the actual throat.

During operation, the gas turbine system 102 may pull air 120 into the compressor 108, which may then compress the air 120 and move the air 120 to the combustion system 110 (e.g., which may include a number of combustors). In the combustion system 110, the fuel nozzle 112 (or a number of fuel nozzles 112) may inject fuel that mixes with the compressed air 120 to create, for example, an air-fuel mixture. The air-fuel mixture may combust in the combustion system 110 to generate hot combustion gases, which flow downstream into the turbine 114 to drive one or more turbine stages. For example, the combustion gases may move through the turbine 114 to drive one or more stages of turbine blades 121, which may in turn drive rotation of a shaft system 122. The shaft system 122 may additionally be coupled to one or more compressor stages having compressor blades 123. The shaft 122 may additionally connect to a load 124, such as a generator that uses the torque of the shaft 122 to produce electricity. After passing through the turbine 114, the hot combustion gases may vent as exhaust gases 126 into the environment by way of the exhaust section 118. The exhaust gas 126 may include gases such as carbon dioxide (CO₂), carbon monoxide (CO), nitrogen oxides (NOₓ), and so forth.

The exhaust gas 126 may include thermal energy, and the thermal energy may be recovered by a heat recovery steam generation (HRSG) system 128. In combined cycle systems, such as the power plant 100, hot exhaust 126 may flow from the gas turbine 114 and pass to the HRSG 128, where it may be used to generate high-pressure, high-temperature steam. The steam produced by the HRSG 128 may then be passed through a steam turbine engine for further power generation. In addition, the produced steam may also be supplied to any other processes where steam may be used, such as to a gasifier used to combust the fuel to produce the untreated syngas. The gas turbine engine generation cycle is often referred to as the “topping cycle,” whereas the steam turbine engine generation cycle is often referred to as the “bottoming cycle.” Combining these two cycles may lead to greater efficiencies in both cycles. In particular, exhaust heat from the topping cycle may be captured and used to generate steam for use in the bottoming cycle.

To better illustrate the generation of the inspection requirements by the inspection requirement generation system 47, an example is provided in relation to the gas turbine 114. The gas turbine 114 may include a throat formed between vanes of a nozzle of the gas turbine 114. The inspection requirement generation system 47 may iterate through a CAD model of the nozzle of the gas turbine 114 to generate inspection requirements along the vanes of the nozzle. The inspection requirement generation system 47 may output a CMM input file that includes the inspection requirements. The CMM system may complete an inspection in accordance with the CMM input file. Further, the actual location and size of the throat may be determined based on the measurements obtained by the CMM system. Further, certain operating parameters (e.g., a flow rate between the vanes) of the gas turbine 114 may be determined based on the actual location and size of the throat. The determined operating parameters may allow for certain adjustments to the operation of the power production system 100. As such, the inspection requirement generation system 47 enables more efficient operation of the power production system 100 and/or portions thereof.

In certain embodiments, the system 100 may also include a controller 130. The controller 130 may be communicatively coupled to a number of sensors 132, a human machine interface (HMI) operator interface 134, and one or more actuators 136 suitable for controlling components of the system 100. The actuators 136 may include valves, switches, positioners, pumps, and the like, suitable for controlling the various components of the system 100. The controller 130 may receive data from the sensors 132, and may be used to control the compressor 108, the combustors 110, the turbine 114, the exhaust section 118, the load 124, the HRSG 128, and so forth.

In certain embodiments, the HMI operator interface 134 may be executable by one or more computer systems of the system 100. A plant operator may interface with the industrial system 100 via the HMI operator interface 134. Accordingly, the HMI operator interface 134 may include various input and output devices (e.g., mouse, keyboard, monitor, touch screen, or other suitable input and/or output device) such that the plant operator may provide commands (e.g., control and/or operational commands) to the controller 130.

The controller 130 may include a processor(s) 140 (e.g., a microprocessor(s)) that may execute software programs to perform the disclosed techniques. Moreover, the processor 140 may include multiple microprocessors, one or more “general-purpose” microprocessors, one or more special-purpose microprocessors, and/or one or more application specific integrated circuits (ASICS), or some combination thereof. For example, the processor 140 may include one or more reduced instruction set (RISC) processors. The controller 130 may include a memory device 142 that may store information such as control software, look up tables, configuration data, etc. The memory device 142 may include a tangible, non-transitory, machine-readable medium, such as a volatile memory (e.g., a random access memory (RAM)) and/or a nonvolatile memory (e.g., a read-only memory (ROM), flash memory, a hard drive, or any other suitable optical, magnetic, or solid-state storage medium, or a combination thereof).

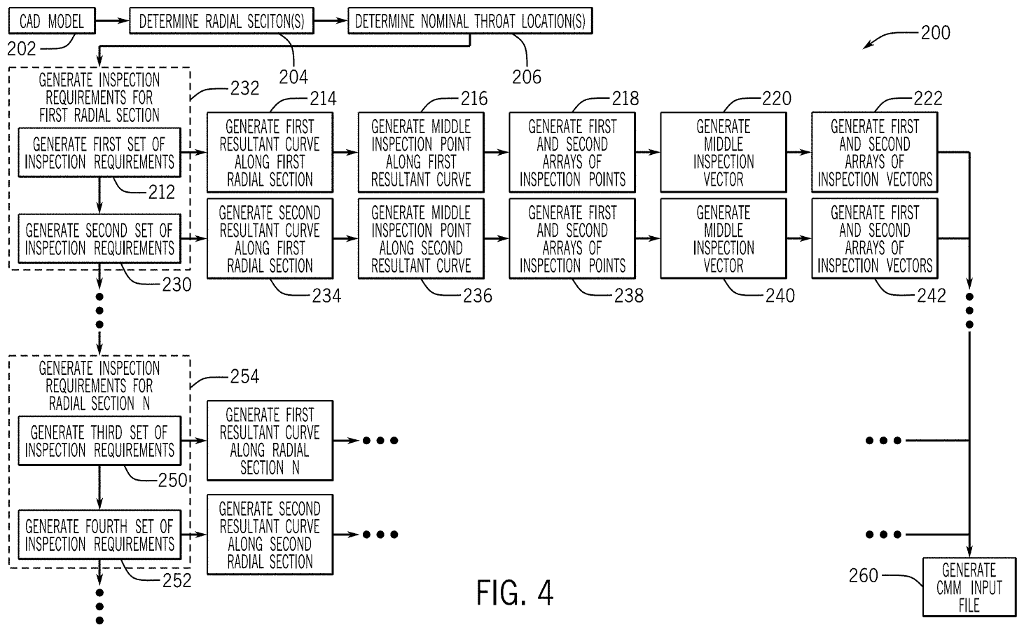

As described above, components of the power production system 100 may be inspected to ensure certain design requirements are met and to determine certain parameters of the power production system 100. For example, a turbine nozzle of the power production system 100 may be inspected to determine a size and a location of an actual throat of the nozzle. Based on the measured size and actual location of the throat, certain operating parameters of the turbine nozzle may be adjusted to optimize the power produced by the power production system 100. With this in mind, FIG. 4 is flow chart of an embodiment of a process 200 suitable for generating a set of inspection requirements for a turbine nozzle via the CAx system 10 of FIG. 1 and/or via the inspection requirement generation system 47 of FIG. 2. For example, the process 200 may be implemented as computer code or instructions stored in the memory 26 and executable via the processor 24. Additionally or alternatively, the process 200 may be implemented in hardware, such as in a custom chip, FPGA chip, and so on. Further, the process 200 may be executable via the cloud 74.

In the depicted embodiment, the process 200 may use a CAD model 202 as an input to generate the inspection requirements. For example, the inspection requirement generation system 47 may be used to display on a computing system display the CAD model 202 via the CAD system 32 of FIG. 2. The CAD model 202 may include all or portions of the power production system 100. For example, the CAD model 202 may include a turbine nozzle having vanes. As described below, the inspection requirement generation system 47 may generate inspection requirements based on the CAD model 202. Such inspection requirements may include inspection points along portions of the CAD model, inspection vectors defining travel paths of an inspection system (e.g., the CMM system 38) to the inspection points, and other inspection requirements related to a throat.

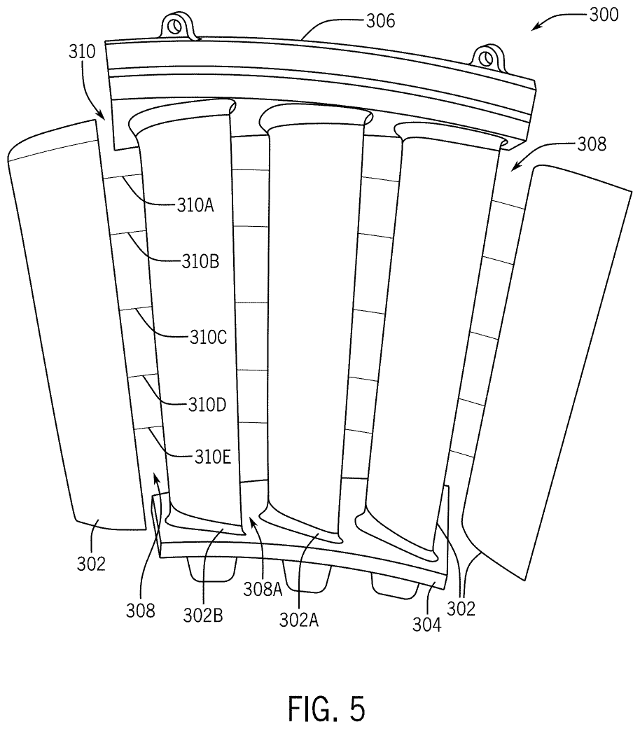

After receiving and/or displaying the CAD model 202, the inspection requirement generation system 47 may automatically determine radial section(s) (e.g., block 204) of the turbine nozzle within the CAD model 202. For example, FIG. 5 is a perspective view of an embodiment of the CAD model including a portion of a turbine nozzle 300 having vanes 302. As illustrated, the vanes 302 are rigidly coupled to an inner side wall 304 and to an outer side wall 306. As described herein, the turbine nozzle 300 acts to control fluid (e.g., air) through openings 308 formed between the vanes 302. The vanes 302 direct and/or compress the fluid flowing through the turbine nozzle 300.

In certain embodiments, the CAD model may be used as a reference in the manufacture of the turbine nozzle 300. For example, a casting of the turbine nozzle 300, or portion(s) of the turbine nozzle 300, may be produced based on drawings produced from the CAD model. The manufacturing process for the turbine nozzle 300 may include certain tolerance values such that the openings 308 formed between the vanes 302 of the casting may vary (i.e., certain portions of the openings 308 may be narrower than other portions). As the fluid flows through a respective opening 308 between two vanes 302, the narrower portions of the opening 308 may block the fluid flow more than other portions of the opening 308. As such, one or more of the narrower portions may form a throat between the two vanes 302. A size and a location of the throat along the opening 308 and along each of the two vanes 302 may be useful to determine certain aspects of the power generation system. For example, the size and the location of the throat may be used to determine an efficiency, an amount of generated power, and other values associated with operation of the power generation system. Accordingly, it may be beneficial to determine the actual throat characteristics to derive real-world knowledge of how a manufactured part will perform.

As illustrated, each opening 308 includes radial sections 310 spanning a width of each opening 308 between the vanes 302. For example, an opening 308A includes radial sections 310A, 310B, 310C, 310D, and 310E located along a width of the opening 308A between a first vane 302A and a second vane 302B. Each radial section 310 extends along a two-dimensional plane between the vanes 302. Further, each radial section 310 is generally parallel to the inner side wall 304 and the outer side wall 306 and is generally perpendicular to the respective vanes 302. In certain embodiments, each opening 308 may include more or fewer radial sections 310 (e.g., one radial section 310, two radial sections 310, three radial sections 310, four radial sections 310, six radial sections 310).

As described herein, the inspection requirement generation system 47 may generate inspection requirements at each radial section 310. For example, the inspection requirement generation system 47 may first automatically determine a number of radial sections 310 and a location of each radial section 310 along the opening 308. In certain embodiments, the inspection requirement generation system 47 may receive a user input indicative of the number of radial sections 310 and the location of each radial section 310 along the opening 308 (e.g., between and along the vanes 302). For example, in the illustrated embodiment, the inspection requirement generation system 47 may define the radial sections 310A, 310B, 310C, 310D, and 310E along the opening 308A, each having a particular location. The number and the locations of the radial sections 310 may be determined based upon a desired granularity of the inspection requirements, certain inspection tolerances, the part design, other factors that may affect determination of the size and location of the throat, or a combination thereof. In certain embodiments, the inspection requirement generation system 47 may provide a dialog box, via the CAD system 32, via the CAE system 34, and/or independently, that provides selectable options for the granularity of the inspection requirements, the inspection tolerances, aspects of the part design, and the other factors. Based on a selected subset of the selectable options, the inspection requirement generation system 47 may automatically determine the number and the locations of the radial sections 310.

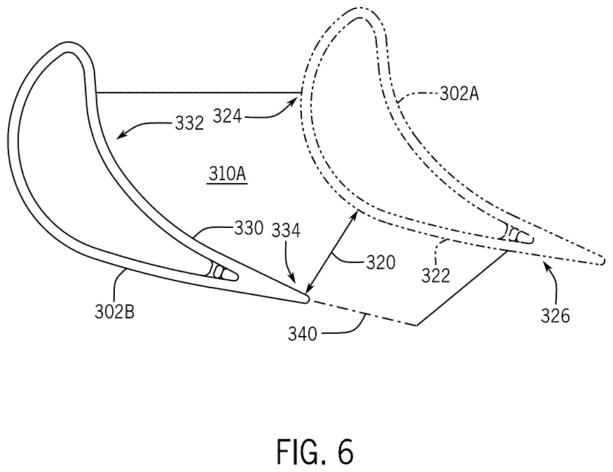

Returning to the process 200 of FIG. 4, after determining and generating the radial sections along the openings of the turbine nozzle (e.g., block 204), the inspection requirement generation system 47 automatically determines a nominal throat location at each radial section 310 (e.g., block 206). As used herein, the nominal throat location refers to the location of the throat within the CAD model. For instance, FIG. 6 is a cross-sectional view of an embodiment of the turbine nozzle 300 of FIG. 5 having a nominal throat location 320 between the first vane 302A and the second vane 302B. Each radial section 310 may include the nominal throat location 320. For example, the nominal throat location 320 is the shortest distance between the first vane 302A and the second vane 302B within the first radial section 310A. The inspection requirement generation system 47 may automatically determine the nominal throat location 320 based on respective locations of the first vane 302A and the second vane 302B within the CAD model. The inspection requirement generation system 47 may iterate through the CAD model to determine the nominal throat location 320 at each radial section 310.

As illustrated, the first vane 302A includes a suction side 322 that extends convexly from a leading edge 324 to a trailing edge 326 of the first vane 302A. The second vane 302B includes a pressure side 330 that extends concavely from a leading edge 332 to a trailing edge 334 of the second vane 302B. As the fluid flows through the first radial section 310A, a first pressure of the fluid may generally be lower along the suction side 322 compared to a second pressure of the fluid along the pressure side 330. As described in greater detail below, the inspection requirement generation system 47 may generate a first set of inspection requirements along the suction side 322 of the first vane 302A and a second set of inspection requirements along the pressure side 330 of the second vane 302B. The first set of inspection requirements may be generally disposed about the nominal throat location 320 along the suction side 322. The second set of inspection requirements may be generally disposed about the nominal throat location 320 along the pressure side 330 and along a phantom edge 340. The phantom edge 340 is an extension of the second vane 302B that is tangent to the surface of the second vane 302B at the nominal throat location 320. Because the nominal throat location 320 at the second vane 302B is generally disposed at the trailing edge 334, the phantom edge 340 is included to account for tolerance ranges of the trailing edge 334. For example, a location of the trailing edge 334 may vary among some vanes 302. The phantom edge 340 provides an extension of the trailing edge 334 to enable generation of the second set of inspection requirements along the pressure side 330 of the second vane 302B.

Returning to FIG. 4, after determining the nominal throat location 320 for each radial section (e.g., block 206), the inspection requirement generation system 47 proceeds to an inspection requirement generation process 210. In the inspection requirement generation process 210, the inspection requirement generation system 47 generates a first set of inspection requirements (e.g., block 212) based on the nominal throat location 320. The first set of inspection requirements are generally located along the suction side 322 of the first vane 302A of FIG. 6. To generate the first set of inspection requirements (e.g., block 212), the inspection requirement generation process 210 includes generating a first resultant curve along the first radial section (e.g., block 214), generating a middle inspection point along the first resultant curve (e.g., block 216) at the nominal throat location 320, generating first and second arrays of inspection points (e.g., block 218), generating a middle inspection vector (e.g., block 220), and generating first and second arrays of inspection vectors (e.g., block 222).

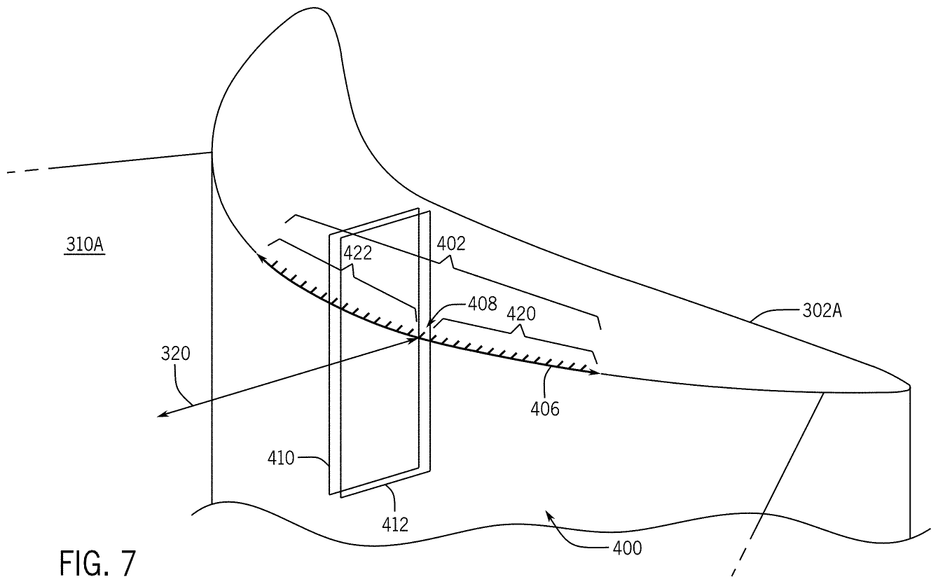

To better illustrate generating the first set of inspection requirements, FIG. 7 is a perspective cross-sectional view of an embodiment of a portion of a first set of inspection requirements 400 along the first vane 302A and along first radial section 310A of FIG. 5. As illustrated, the first set of inspection requirements 400 includes inspection points 402. Each inspection point 402 is a location along a surface of the first vane 302A at which the location may be measured. The inspection requirement generation system 47 of FIG. 2 first generates a first resultant curve 406 along the first radial section 310A and along the first vane 302A (e.g., block 214 of FIG. 4). The first resultant curve 406 follows a contour of the surface of the first vane 302A along the first radial section 310A. The inspection requirement generation system 47 also generates a middle inspection point 408 along the first resultant curve 406 (e.g., block 216 of FIG. 4) at an intersection of the nominal throat location and the first resultant curve 406. The inspection points 402 include the middle inspection point 408 at a center of the inspection points 402.

The inspection requirement generation system 47 then determines/generates a middle plane 410 that extends along and is parallel to the nominal throat location. The middle plane 410 is also generally perpendicular to the first resultant curve 406 and intersects the first resultant curve 406 at the middle inspection point 408. Thereafter, the inspection requirement generation system 47 determines/generates a first array of planes and a second array of planes parallel to the middle plane 410 and on either side of the plane 410. As illustrated, a plane 412 of the first array of planes is positioned parallel the middle plane 410. Similar to the plane 412, the inspection requirement generation system 47 may generate the rest of the first array of planes on the same side of the middle plane 410 as the plane 412. Additionally, the inspection requirement generation system 47 may generate the second array of planes on the opposite side of the middle plane 410 from the plane 412. However, to better show the planes 410 and 412, along with their corresponding inspection points 402, only the planes 410 and 412 are illustrated in FIG. 7. The spacing between each plane may vary among embodiments. For example, the spacing may be 0.5 millimeters (mm) in a first embodiment and other sizes (e.g., 0.1 mm, 0.2 mm, 0.4 mm, 1 mm, 5 mm) in other respective embodiments.

The inspection requirement generation system 47 then generates a first array of inspection points 420 and a second array of inspection points 422 (e.g., block 218 of FIG. 4). Each inspection point of the first array of inspection points 420 is located at an intersection of the first resultant curve 406 and a corresponding plane of the first array of planes. Each inspection point of the second array of inspection points 422 is located at an intersection of the first resultant curve 406 and a corresponding plane of the second array of planes. The middle inspection point 408 is located between the first array of inspection points 420 and the second array of inspection points 422. Further, the inspection points 402 include the middle inspection point 408, the first array of inspection points 420, and the second array of inspection points 422.

The middle inspection point 408 is located at the nominal throat location, because, in certain embodiments, the middle inspection 408 is the most likely location of the actual throat along the first vane 302A. For example, if the nozzle is manufactured precisely in accordance with the CAD model 202, the actual throat of the nozzle will be located at the nominal throat location. Further, the first set of inspection requirements 400 includes the first array of inspection points 420 and the second array of inspection points 422 on either side of the middle inspection point 408 to account for possible variations in the actual throat. As such, the first set of inspection requirements 400 provides for various inspectable locations along the first vane 302A to enable determination of the actual throat.

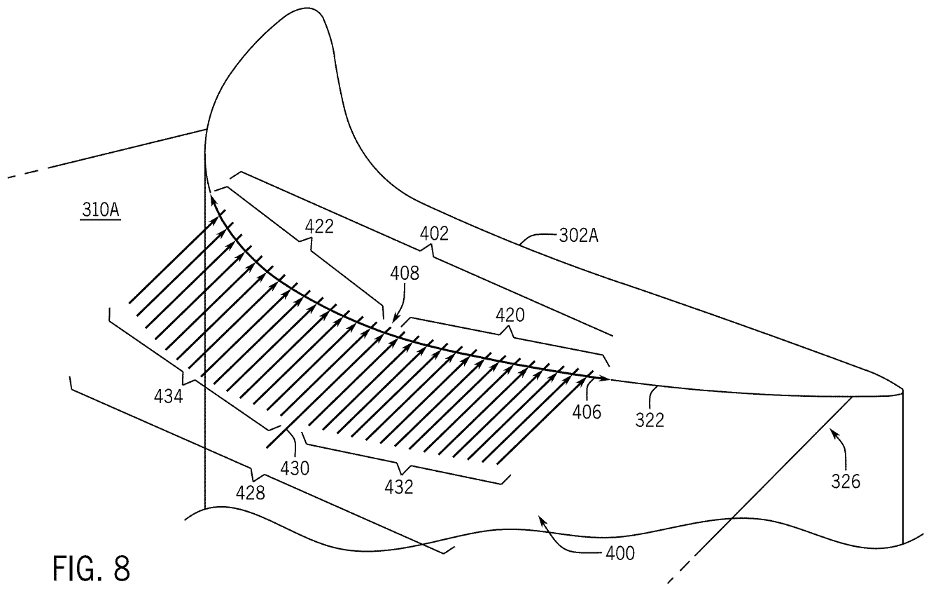

FIG. 8 is a perspective cross-sectional view of an embodiment of the first set of inspection requirements 400 along the first vane 302A and along first radial section 310A of FIG. 7. As illustrated, the first set of inspection requirements 400 includes the inspection points 402 and inspection vectors 428. Each inspection vector 428 intersects with a corresponding inspection point 402 along the first vane 302A and extends into the first radial section 310A. Additionally, each inspection vector 428 defines a path that a measurement device may follow to measure a corresponding inspection point 402. For example, the CMM system described herein may follow the inspection vectors 428 to measure the location of corresponding inspection points 402.

To provide the inspection vectors 428, the inspection requirement generation system 47 generates a middle inspection vector 430 (e.g., block 220 of FIG. 4) that intersects the middle inspection point 408 and extends into the first radial section 310A (e.g., into the two-dimensional plane defined by the first radial section 310A). The middle inspection vector 430 is normal to the first vane 302A at the middle inspection point 408. As such, the middle inspection vector 430 extends from and normal to the first vane 302A at the middle inspection point 408. In certain embodiments, the middle inspection vector 430 may be disposed at other angles relative to the vane 302A. The inspection requirement generation system 47 then generates a first array of inspection vectors 432 and a second array of inspection vectors 434. The first array of inspection vectors 432 are located on a first side of the middle inspection vector 430, and the second array of inspection vectors 434 are located on a second side of the middle inspection vector 430 that is generally opposite of the first side of the middle inspection vector 430. Additionally, each inspection vector of the first array of inspection vectors 432 and the second array of inspection vectors 434 is parallel to the middle inspection vector 430 and intersects the first resultant curve 406. As illustrated, each inspection vector of the inspection vectors 428 (e.g., the middle inspection vector 430, the first array of inspection vectors 432, and the second array of inspection vectors 434) is spaced equally apart from one another, and each inspection vector of the inspection vectors 428 extends along the first radial section 310A.

In the illustrated embodiment, the first set of inspection requirements 400 includes twenty-nine inspection points 402 (i.e., the middle inspection point 408, fourteen inspection points of the first array of inspection points 420, and fourteen inspection points of the second array of inspection points 422). The first set of inspection requirements 400 also includes twenty-nine corresponding inspection vectors 428 (i.e., the middle inspection vector 430, fourteen inspection vectors of the first array of inspection vectors 432, and fourteen inspection vectors of the second array of inspection vectors 434). However, in certain embodiments, the inspection points 402 may include more or fewer inspection points, and the inspection vectors 428 may include more or fewer corresponding inspection vectors. The number of inspection points and the corresponding number of inspection vectors may depend on a desired granularity of the measurements obtained based on the inspection requirements, certain tolerances, the part design, other factors affecting determination of the size and location of the actual throat, or a combination thereof. For example, the twenty-nine inspection points 402 and the twenty-nine corresponding inspection vectors 428 in the illustrated embodiment enable measurement of the first vane 302A and accurate determination of the actual throat along the first vane 302A without overburdening an inspection system (e.g., the CMM system). In certain embodiments, the inspection requirement generation system 47 may provide a dialog box with selectable options including a selectable number of inspection points and corresponding inspection vectors.

Each inspection vector of the inspection vectors 428 defines a path by which a measuring device may travel to measure a corresponding inspection point of the inspection points 402. For example, the middle inspection vector 430 defines a path that a measuring device (e.g., a probe of the CMM system) may travel to measure middle inspection point 408. The defined and consistent measurement paths (e.g., the inspection vectors 428) for measuring the inspection points 402 enable greater consistency and easier comparison and analysis among inspection reports. Moreover, the consistent spacings between the inspection vectors 428, as well as the parallel positioning of the inspection vectors 428, ensures consistency in the methodology of collecting measurements for each inspection point 402.

Returning to FIG. 4, the inspection requirements generation process 210 also includes generating a second set of inspection requirements (e.g., block 230). The second set of inspection requirements are generally located along the pressure side 330 of the second vane 302B of FIG. 6. As such, the first set of inspection requirements and the second set of inspection requirements may be generated for the first radial section 310A, as indicated by block 232. To generate the second set of inspection requirements (e.g., block 230), the inspection requirement generation process 210 includes generating a second resultant curve along the first radial section (e.g., block 234), generating a middle inspection point along the second resultant curve (e.g., block 236), generating first and second arrays of inspection points (e.g., block 238), generating a middle inspection vector (e.g., block 240), and generating first and second arrays of inspection vectors (e.g., block 242).

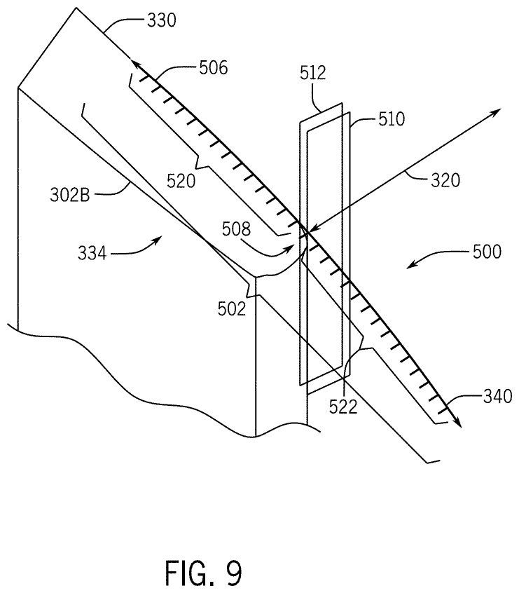

To better illustrate generating the second set of inspection requirements, FIG. 9 is a perspective cross-sectional view of an embodiment of a second set of inspection requirements 500 along the second vane 302B and along the first radial section 310A of FIG. 5. As illustrated, the second set of inspection requirements 500 includes inspection points 502. Each inspection point 502 is a location along the second vane 302B at which the location may be measured. The inspection requirement generation system 47 generates a second resultant curve 506 along the first radial section 310A and along the second vane 302B (e.g., block 234 of FIG. 4). The second resultant curve 506 follows a contour of the surface of the second vane 302B along the first radial section 310A. The inspection requirement generation system 47 also generates a middle inspection point 508 along the second resultant curve 506 (e.g., block 236 of FIG. 4) at an intersection of the nominal throat location and the second resultant curve 506. The inspection points 502 include the middle inspection point 508 at a center of the inspection points 502.

The inspection requirement generation system 47 then determines/generates a middle plane 510 that extends along and is parallel to the nominal throat location. The middle plane 510 is also generally perpendicular to the second resultant curve 506 and intersects the second resultant curve 506 at the middle inspection point 508. Thereafter, the inspection requirement generation system 47 determines/generates a first array of planes and a second array of planes parallel to the middle plane 510 and on either side of the plane 510. As illustrated, a plane 512 of the first array of planes is positioned parallel the middle plane 510. Similar to the plane 512, the inspection requirement generation system 47 may generate the rest of the first array of planes on the same side of the middle plane 510 as the plane 512. Additionally, the inspection requirement generation system 47 may generate the second array of planes on the opposite side of the middle plane 510 from the plane 512. However, to better show the planes 510 and 512, along with their corresponding inspection points 502, only the planes 510 and 512 are illustrated in FIG. 7. The spacing between each plane may vary among embodiments. For example, the spacing may be 0.5 millimeters (mm) in a first embodiment and other sizes (e.g., 0.1 mm, 0.2 mm, 0.4 mm, 1 mm, 5 mm) in other respective embodiments.

The inspection requirement generation system 47 then generates a first array of inspection points 520 and a second array of inspection points 522 (e.g., block 238 of FIG. 4). Each inspection point of the first array of inspection points 520 is located at an intersection of the second resultant curve 506 and a corresponding inspection plane of the first array of planes. Each inspection point of the second array of inspection points 522 is located at an intersection of the second resultant curve 506 and a corresponding plane of the second array of planes. The middle inspection point 508 is located between the first array of inspection points 520 and the second array of inspection points 522. Further, the inspection points 502 include the middle inspection point 508, the first array of inspection points 520, and the second array of inspection points 522.

The middle inspection point 508 is located at the nominal throat location, because, in certain embodiments, the middle inspection 508 is the most likely location of the actual throat along the second vane 302B. Further, the second set of inspection requirements 500 includes the first array of inspection points 520 and the second array of inspection points 522 on either side of the middle inspection point 508 to account for possible variations in the actual throat. As such, the second set of inspection requirements 500 provides for various inspectable locations along the second vane 302B to enable determination of the actual throat.

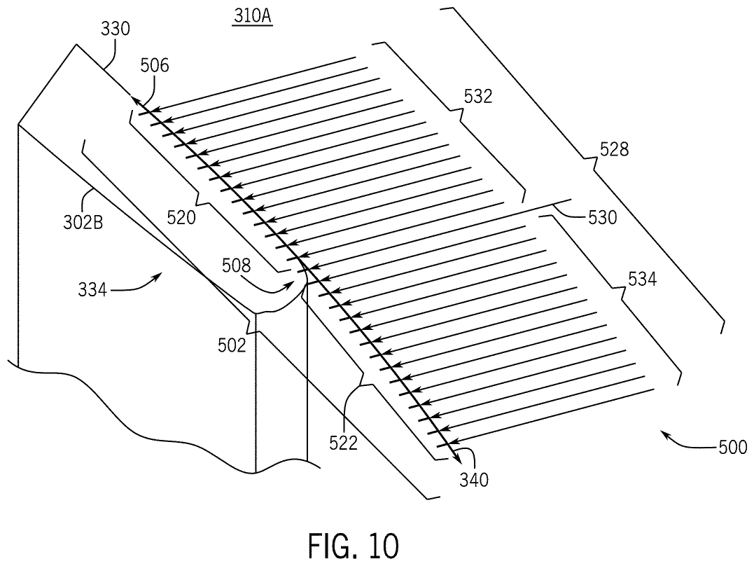

FIG. 10 is a perspective cross-sectional view of an embodiment of the second set of inspection requirements 500 along the second vane 302B and along the first radial section 310A of FIG. 9. As illustrated, the second set of inspection requirements 500 includes the inspection points 502 and inspection vectors 528. Each inspection vector 528 intersects with a corresponding inspection point 502 at the pressure side 330 of the second vane 302B and extends into the first radial section 310A. Additionally, each inspection vector 528 defines a path that a measurement device may follow to measure a corresponding inspection point 502. For example, the CMM system described herein may follow the inspection vectors 528 to measure the location of corresponding inspection points 502.

To provide the inspection vectors 528, the inspection requirement generation system 47 generates a middle inspection vector 530 (e.g., block 240 of FIG. 4) that intersects the middle inspection point 508 and extends along the first radial section 310A. As illustrated, the middle inspection vector 530 is normal to the second vane 302B. In certain embodiments, the middle inspection vector 530 may be disposed at other angles relative to the second vane 302B. The inspection requirement generation system 47 then generates a first array of inspection vectors 532 and a second array of inspection vectors 534. The first array of inspection vectors 532 are located on a first side of the middle inspection vector 530, and the second array of inspection vectors 534 are located on a second side of the middle inspection vector 530 that is generally opposite of the first side of the middle inspection vector 530. Additionally, each inspection vector of the first array of inspection vectors 532 and the second array of inspection vectors 534 is parallel to the middle inspection vector 530 and intersects the second resultant curve 506. As illustrated, each inspection vector of the inspection vectors 528 (e.g., the middle inspection vector 530, the first array of inspection vectors 532, and the second array of inspection vectors 534) is spaced equally apart from one another, and each inspection vector of the inspection vectors 528 extends along the first radial section 310A.

The defined and consistent measurement paths (e.g., the inspection vectors 528) for measuring the inspection points 502 enable greater consistency and easier comparison and analysis among inspection reports. Moreover, the consistent spacings between the inspection vectors 528, as well as the parallel positioning of the inspection vectors 528, ensures consistency in the methodology of collecting measurements for each inspection point 502.

In the illustrated embodiment, the second set of inspection requirements 500 includes twenty-nine inspection points 502 (i.e., the middle inspection point 508, fourteen inspection points of the first array of inspection points 520, and fourteen inspection points of the second array of inspection points 522). The second set of inspection requirements 500 also includes twenty-nine corresponding inspection vectors 528 (i.e., the middle inspection vector 530, fourteen inspection vectors of the first array of inspection vectors 532, and fourteen inspection vectors of the second array of inspection vectors 534). However, in certain embodiments, the inspection points 502 may include more or fewer inspection points, and the inspection vectors 528 may include more or fewer corresponding inspection vectors. The number of inspection points and the corresponding number of inspection vectors may depend on a desired granularity of the measurements obtained based on the inspection requirements, certain tolerances, the part design, other factors affecting determination of the size and location of the actual throat, or a combination thereof. For example, the twenty-nine inspection points 502 and the twenty-nine corresponding inspection vectors 528 in the illustrated embodiment enable measurement of the second vane 302B and accurate determination of the actual throat along the second vane 302B without overburdening an inspection system (e.g., the CMM system).

Each inspection vector of the inspection vectors 528 defines a path by which a measuring device may travel to measure a corresponding inspection point of the inspection points 502. For example, the middle inspection vector 530 defines a path that a measuring device may travel to measure middle inspection point 508. The defined and consistent measurement paths (e.g., the inspection vectors 528) for measuring the inspection points 502 enable greater consistency and easier comparison and analysis among inspection reports. Moreover, the consistent spacings between the inspection vectors 528, as well as the parallel positioning of the inspection vectors 528, ensures consistency in the methodology of collecting measurements for each inspection point 502.

Returning to FIG. 4, after generating the first set of inspection requirements (e.g., block 212) and generating the second set of inspection requirements (e.g., block 230), the inspection requirement generation process 210 may proceed to generating inspection requirements for a second radial section. For example, the inspection requirement generation system 47 may generate a third set of inspection requirements (e.g., block 250) for the suction side of the first vane 302A and may generate a fourth set of inspection requirements (e.g., block 252) for the pressure side of the second vane. As indicated by block 254, the third and fourth sets of inspection requirements are for a radial section N (e.g., the second radial section 310B, the third radial section 310C, the fourth radial section 310D, the fifth radial section 310E, or another radial section 310). Generating the third set of inspection requirements may generally follow similar steps as those described above for generating the first set of inspection requirements (e.g., blocks 214, 216, 218, 220, and 222). Additionally, generating the fourth set of inspection requirements may generally follow similar steps as those described above for generating the second set of inspection requirements (e.g., blocks 234, 236, 238, 240, and 242). Further, the inspection requirement generation system 47 may generate inspection requirements for each additional radial section N (e.g., the second radial section 310B, the third radial section 310C, the fourth radial section 310D, the fifth radial section 310E).

As described herein, the first and second sets of inspection requirements may be generated for the first radial section 310A of FIG. 5, and the third and fourth sets of inspection requirements may be generated for the radial section N. Further, sets of inspection requirements may be generated for any number of the radial sections 310 (e.g., one radial section 310, two radial sections 310, three radial sections 310, four radial sections 310, five radial sections 310, ten radial sections 310, twenty radial sections 310, etc.).

After generating the various sets of inspection requirements (e.g., the first set of inspection requirements, the second set of inspection requirements, etc.), the process 200 proceeds to generating and outputting a CMM input file (e.g., block 260). For example, the inspection requirement generation system 47 may generate a CMM input file that includes each set of inspection requirements generated during the inspection requirement generation process 210. The inspection requirement generation system 47 may provide the CMM input file directly to a CMM system (e.g., the CMM system 38 of FIG. 2) or may provide the file to be uploaded to the CMM system. As such, the CMM system may directly read the CMM input file and each set of inspection requirements to measure the respective inspection points. By way of example, the inspection requirements of the CMM file may read as: “FIRST SET OF INSPECTION REQUIREMENTS: [INSPECTION POINT ONE], [INSPECTION VECTOR ONE], [INSPECTION POINT TWO], [INSPECTION VECTOR TWO] . . . SECOND SET OF INSPECTION REQUIREMENTS: [INSPECTION POINT ONE], [INSPECTION VECTOR ONE], [INSPECTION POINT TWO], [INSPECTION VECTOR TWO] . . . ” In certain embodiments, the inspection requirements of the CMM file may read differently.

The CMM input file may be received by the CMM system. The CMM system may perform measurements based on the CMM input file. The CMM measurements may be used to determine an actual throat location and throat size of an opening of the turbine nozzle. As may be appreciated, the actual throat may be beneficial in analysis of manufactured parts. For example, the actual throat may be compared with the designed throat of the CAD model (e.g., the nominal throat) to identify how well the manufactured part matches the design, whether the manufactured part is within tolerance, and/or to identify potential manufacturing improvements.

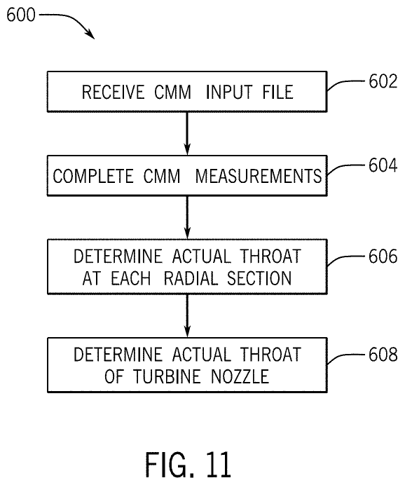

For example, FIG. 11 is flow chart of an embodiment of a process 600 suitable for measuring and determining a throat location and size of a respective opening 308 of the turbine nozzle 300 of FIG. 5 using the CMM input file. The CMM system first receives the CMM input file (e.g., block 602) directly from the inspection requirement generation system 47. In certain embodiments, the CMM system may receive the CMM input file that was generated by the inspection requirement generation system 47 from another source. The CMM system then completes CMM measurements in accordance with the CMM input file (e.g., block 604). For example, as described herein, the CMM input file may include set(s) of inspection requirements for each radial section 310 of the turbine nozzle 300 of FIG. 5. The CMM system may complete the CMM measurements for each radial section 310 and for each respective opening 308. As a result, the CMM may measure the location of each inspection point included in the CMM input file and may generate an inspection report that includes each of the measured locations.

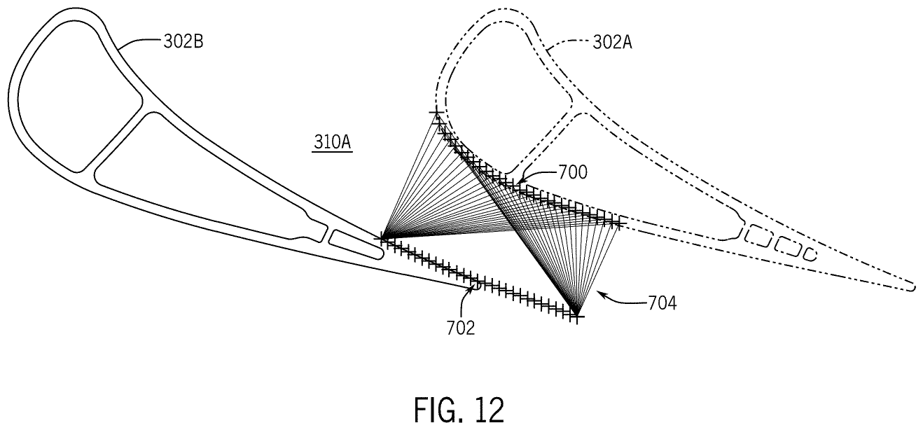

After generating the inspection report, the actual throat size and location along each radial section may be determined. For example, FIG. 12 is a cross-sectional view of an embodiment of the first vane 302A and the second vane 302B of FIG. 5 with a first set of measured points 700 along the first vane 302A and a second set of measured points 702 along the second vane 302B. As illustrated, the first set of measured points 700 includes twenty-nine measured points along the first vane 302A, and the second set of measured points includes twenty-nine measured points along the second vane 302B. Each measured point corresponds to an inspection point of the CMM input file. For example, each measured point of the first set of measured points 700 may correspond to an inspection point 402 along the first vane 302A of FIG. 7. Additionally, each measured point of the second set of measured points 702 may correspond to an inspection point 502 along the second vane 302B of FIG. 8. As such, in certain embodiments, the first set of measured points 700 and the second set of measured points 702 may include more or fewer measured points depending on the CMM input file.

Returning to FIG. 11, the size and location of the actual throat at each radial section may be determined (e.g., block 606) based on the respective locations of each measured point of the first set of measured points 700 and the second set of measured points 702. For example, as illustrated in FIG. 12, connecting lines 704 are positioned between the first set of measured points 700 and the second set of measured points 702. The length of each connecting line 704 represents a distance between a respective measured point of the first set of measured points 700 and a respective measured point of the second set of measured points 702. Further, while only fifty-eight connecting lines 704 are illustrated, the first radial section 310A may include connecting lines 704 that connect each respective measured point of the first set of measured points 700 to each respective measured point of the second set of measured points 702. As such, 841 total connecting lines 704, and their respective lengths, may be determined based on the respective locations of each measured point of the first set of measured points 700 and the second set of measured points 702. The shortest line of the connecting lines 704 indicates the actual throat of the first radial section 310A. For example, the measured point of the first set of measured points 700 and the measured point of the second set of measured points 700 that connect the shortest line represent the location of the actual throat along the first radial section 310A (e.g., along the first vane 302A and along the second vane 302B). Additionally, the distance between the two points (e.g., the length of the shortest line) represents the size of the actual throat at the first radial section 310A.

Returning to FIG. 11, the size and location of the actual throat of the turbine nozzle, or of an opening within the turbine nozzle, may be determined (e.g., block 608). For example, block 606 may be repeated for each radial section 310 of the respective opening 308A of FIG. 5. The size and location of the actual throat for each radial section 310 may be determined. The respective actual throats at each radial section 310 may be used to determine the actual throat of the opening 308A. The actual throat of the opening 308A may span the length of the opening 308A. Additionally, each of the process 200 of FIG. 4 and the process 600 of FIG. 11 may be repeated for each opening 308 of FIG. 5 to determine the actual throat of each opening 308.

The location and size of the actual throat of each opening 308 may be used to determine various technical parameters associated with the turbine nozzle 300. For example, the actual throat may be used determine a flow rate, an efficiency, generated power, fuel consumption, and other technical parameters. Each of the process 200 of FIG. 4 and the process 600 of FIG. 11 may be automatically performed for the turbine nozzle 300. For example, the inspection requirement generation system 47 may perform the process 200 or portions thereof (e.g., the inspection requirement generation process 210), and certain systems described herein (e.g., the systems 30, 32, 34, 36, 38, 40, or a combination thereof) may perform the process 600 or portions thereof.

Technical effects of the subject matter disclosed herein include, but are not limited to, automatically generating inspection requirements to determine an actual throat of a turbine nozzle. The inspection requirements may be generated by an inspection requirement generation system and may be included in a CMM input file that is read by a CMM system. The CMM system may measure the turbine nozzle in accordance with the inspection requirements of the CMM input file, and the actual throat of the turbine nozzle may be determined based on the CMM measurements. As such, the inspection requirement generation system described herein may automatically generate and provide consistent inspection requirements that may lead to consistent CMM measurements along a nozzle and accurate determination of the actual throat of the nozzle.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A method comprising:
generating, via a processor, a first set of inspection requirements for a first radial section between a first vane and a second vane of a turbine nozzle using an inspection requirement generation process, the inspection requirement generation process comprising:
generating a first resultant curve along the first radial section of the turbine nozzle in a three-dimensional (3D) computer-aided design (CAD) model, wherein the first resultant curve is disposed along the first vane;
generating a middle inspection point along the first resultant curve at a nominal throat location between the first vane and the second vane;
generating a first array of inspection points at intersection locations of a first array of planes and the first resultant curve on a first side of the middle inspection point along the first resultant curve, wherein the first array of planes are generally parallel to the nominal throat location;
generating a second array of inspection points at intersection locations of a second array of planes and the first resultant curve on a second side of the middle inspection point along the first resultant curve, wherein the second array of planes are generally parallel to the nominal throat location;
generating a middle inspection vector, wherein the middle inspection vector is normal to the first vane at the middle inspection point;
generating a first array of inspection vectors on a first side of the middle inspection vector, wherein each inspection vector of the first array of inspection vectors is parallel to the middle inspection vector and intersects the first resultant curve at a respective inspection point of the first array of inspection points; and
generating a second array of inspection vectors on a second side of the middle inspection vector, wherein each inspection vector of the second array of inspection vectors is parallel to the middle inspection vector and intersects the first resultant curve at a respective inspection point of the second array of inspection points, and wherein the first set of inspection requirements comprises the middle inspection point measured from the middle inspection vector, the first array of inspection points measured from respective inspection vectors of the first array of inspection vectors, and the second array of inspection points measured from respective inspection vectors of the second array of inspection vectors; and
generating a coordinate measuring machine (CMM) input file comprising the first set of inspection requirements.

2. The method of claim 1, comprising generating a second set of inspection requirements by repeating the inspection requirement generation process for the second vane along the first radial section.

3. The method of claim 2, wherein the CMM input file comprises the first set of inspection requirements and the second set of inspection requirements.

4. The method of claim 2, wherein the first radial section comprises a first cross-sectional area of the turbine nozzle between the first resultant curve along the first vane and a second resultant curve along the second vane.

5. The method of claim 2, wherein the first set of inspection requirements are located on a suction side of the first vane, and the second set of inspection requirements are located on a pressure side of the second vane.

6. The method of claim 2, comprising generating a third set of inspection requirements by repeating the inspection requirement generation process for the first vane along a second radial section.

7. The method of claim 6, comprising generating a fourth set of inspection requirements by repeating the inspection requirement generation process for the second vane along the second radial section.

8. The method of claim 7, comprising iteratively generating additional sets of inspections requirements for additional radial sections, wherein a number of the additional radial sections is based on a desired granularity of the inspection requirements, inspection tolerances, a design of the turbine nozzle, or a combination thereof.

9. The method of claim 1, wherein the first side of the middle inspection point is opposite of the second side of the middle inspection point along the first resultant curve.

10. A computer aided technologies (CAx) system, comprising:
a processor, wherein the processor is configured to:
generate a first set of inspection requirements for a first radial section between a first vane and a second vane of a turbine nozzle using an inspection requirement generation process, the inspection requirement generation process comprising:
generating a first resultant curve along the first radial section of the turbine nozzle in a three-dimensional (3D) computer-aided design (CAD) model, wherein the first resultant curve is disposed along the first vane;
generating a middle inspection point along the first resultant curve at a nominal throat location between the first vane and the second vane;
generating a first array of inspection points at intersection locations of a first array of planes and the first resultant curve on a first side of the middle inspection point along the first resultant curve, wherein the first array of planes are generally parallel to the nominal throat location;
generating a second array of inspection points at intersection locations of a second array of planes and the first resultant curve on a second side of the middle inspection point along the first resultant curve, wherein the second array of planes are generally parallel to the nominal throat location;
generating a middle inspection vector, wherein the middle inspection vector is normal to the first vane at the middle inspection point;
generating a first array of inspection vectors on a first side of the middle inspection vector, wherein each inspection vector of the first array of inspection vectors is parallel to the middle inspection vector and intersects the first resultant curve at a respective inspection point of the first array of inspection points; and
generating a second array of inspection vectors on a second side of the middle inspection vector, wherein each inspection vector of the second array of inspection vectors is parallel to the middle inspection vector and intersects the first resultant curve at a respective inspection point of the second array of inspection points, and wherein the first set of inspection requirements comprises the middle inspection point measured from the middle inspection vector, the first array of inspection points measured from respective inspection vectors of the first array of inspection vectors, and the second array of inspection points measured from respective inspection vectors of the second array of inspection vectors; and
generate a coordinate measuring machine (CMM) input file comprising the first set of inspection requirements.

11. The system of claim 10, wherein the processor is configured to generate a second set of inspection requirements by repeating the inspection requirement generation process for the second vane along the first radial section.

12. The system of claim 11, wherein the first set of inspection requirements and the second set of inspection requirements enable determination of an actual throat of the turbine nozzle at the first radial section.

13. The system of claim 10, wherein each inspection point and each inspection vector of the first set of inspection requirements is identified via a unique identifier within the CMM input file.

14. The system of claim 10, wherein the first array of inspection points comprises fourteen inspection points on the first side of the middle inspection point, and the second array of inspection points comprises fourteen inspection points on the second side of the middle inspection point.

15. The system of claim 10, wherein the CAx system comprises a CAD system, and wherein the processor is configured to determine a location of the first radial section based on an input to the CAD system.

16. A tangible, non-transitory, computer-readable medium comprising instructions that, when executed, are configured to cause a processor to:
generate a first set of inspection requirements for a first radial section between a first vane and a second vane of a turbine nozzle using an inspection requirement generation process, the inspection requirement generation process comprising:
generating a first resultant curve along the first radial section of the turbine nozzle in a three-dimensional (3D) computer-aided design (CAD) model, wherein the first resultant curve is disposed along the first vane;
generating a middle inspection point along the first resultant curve at a nominal throat location between the first vane and the second vane;
generating a first array of inspection points at intersection locations of a first array of planes and the first resultant curve on a first side of the middle inspection point along the first resultant curve, wherein the first array of planes are generally parallel to the nominal throat location;
generating a second array of inspection points at intersection locations of a second array of planes and the first resultant curve on a second side of the middle inspection point along the first resultant curve, wherein the second array of planes are generally parallel to the nominal throat location;
generating a middle inspection vector, wherein the middle inspection vector is normal to the first vane at the middle inspection point;
generating a first array of inspection vectors on a first side of the middle inspection vector, wherein each inspection vector of the first array of inspection vectors is parallel to the middle inspection vector and intersects the first resultant curve at a respective inspection point of the first array of inspection points; and
generating a second array of inspection vectors on a second side of the middle inspection vector, wherein each inspection vector of the second array of inspection vectors is parallel to the middle inspection vector and intersects the first resultant curve at a respective inspection point of the second array of inspection points, and wherein the first set of inspection requirements comprises the middle inspection point measured from the middle inspection vector, the first array of inspection points measured from respective inspection vectors of the first array of inspection vectors, and the second array of inspection points measured from respective inspection vectors of the second array of inspection vectors; and
generate a coordinate measuring machine (CMM) input file comprising the first set of inspection requirements.

17. The tangible, non-transitory, computer-readable medium of claim 16, wherein the instructions are configured to cause the processor to generate a second set of inspection requirements by repeating the inspection requirement generation process for the second vane along the first radial section.

18. The tangible, non-transitory, computer-readable medium of claim 17, wherein the first set of inspection requirements are located on a suction side of the first vane, and the second set of inspection requirements are located on a pressure side of the second vane.

19. The tangible, non-transitory, computer-readable medium of claim 18, wherein the second set of inspection requirements along the second vane are disposed along a trailing edge of the second vane.

20. The tangible, non-transitory, computer-readable medium of claim 16, wherein the instructions are configured to cause the processor to automatically determine the nominal throat location along the first radial section within the CAD model.
